(19) United States
(12) Patent Application Publication
(10) Pub. No.: US 2025/0006455 A1
(43) Pub. Date: Jan. 2, 2025

(54) METHOD FOR OPERATING A PARTICLE BEAM MICROSCOPE

(71) Applicant: Carl Zeiss Microscopy GmbH, Jena (DE)

(72) Inventor: Bjoern Gamm, Koenigsbronn (DE)

(21) Appl. No.: 18/753,764

(22) Filed: Jun. 25, 2024

(30) Foreign Application Priority Data
Jun. 27, 2023 (DE) 10 2023 116 944.0

(51) Int. Cl. H01J 37/21; H01J 37/22; H01J 37/28

(52) U.S. Cl. CPC H01J 37/21; H01J 37/222; H01J 37/28; H01J 2237/1532

(57) ABSTRACT

For a given object direction, a method for operating a particle beam microscope comprises: successively directing a particle beam at a multiplicity of incidence locations within an elongate region of the object oriented in the given object direction, detecting particles and ascertaining a value representing a measure for an image sharpness, and changing an excitation of a stigmator on the basis of the value, with the object of improving the image sharpness. The method also comprises performing the measures for a first given object direction; and performing the measures for a second given object direction which is oriented across the first given object direction.

### CROSS-REFERENCE TO RELATED APPLICATION

This application claims benefit under 35 U.S.C. § 119 to German Application No. 10 2023 116 944.0, filed Jun. 27, 2023. The entire disclosure of this application is incorporated by reference herein.

### FIELD

The present disclosure relates to methods for operating particle beam microscopes.

### BACKGROUND

A conventional particle beam microscope typically comprises a particle beam source for creating a particle beam, an objective lens for focusing the particle beam on an object, a scan deflector for displacing an incidence location of the particle beam on the object and a detector for detecting particles created at the object by the particle beam. By actuating the scan deflector, the particle beam can be successively directed at a multiplicity of incidence locations on the object while intensities of the particles created at the object by the particle beam are detected for each incidence location using the detector. Values representing the detected intensities and values assigned thereto representing the incidence locations of the particle beam can be stored as a data record which represents a particle-microscopic image of the object.

The particle beam microscope is set appropriately so that the images represented by the collected data records have a desired quality, for instance with respect to resolution, image sharpness, contrast and the like. For instance, a high-resolution particle beam-microscopic image can be obtained when the spot on the object exposed by the particle beam is as small as possible. Further, it can be desirable for the particle beam to have as little astigmatic distortion as possible when incident on the object. Further, for objects that are not plane but structured in three dimensions, it can be desirable for the created particle beam-microscopic images to exhibit a sufficient depth of field.

To make desired adjustments on the particle beam microscope, the latter also comprises further particle-optical elements, for example a stigmator for influencing the particle beam astigmatically, an adjustment deflector for deflecting the particle beam such that its position relative to the objective lens is modified and a condenser whose excitation is changeable in order to modify a numerical aperture of the particle beam when incident on the object.

The excitations of the elements in the particle beam microscope are modified within the scope of finding a suitable setting, typically to increase the image sharpness of the recorded images. To this end, many test images of the object are conventionally recorded in an optimization method with modified excitations of these elements, with the images being analysed and compared to one another in order to find an optimal setting for the excitations. Then, the desired particle beam-microscopic images of the object can be obtained using the optimal found setting for the excitations.

While the desired images recorded with the optimized setting typically contain a large number of pixels, the test images recorded to find the optimized setting may have comparatively fewer pixels. However, even for particle-microscopic test images with a reduced number of pixels it can be desirable for the particle beam to be directed at the multiplicity of incidence locations on the object corresponding to the pixels and for a statistically representative number of particles to be detected for the respective incidence location. This usually means that each test image in the optimization process involves a non-negligible recording time, and the optimization process overall takes up a significant period of time. This period of time is often perceived as being too long.

### SUMMARY

The present disclosure proposes a method for operating a particle beam microscope, which shortens the time taken up by a procedure for setting up the particle beam microscope.

According to an aspect of the disclosure, the method for operating a particle beam microscope is applied to a particle beam microscope which comprises a particle beam source for creating a particle beam, an objective lens for focusing the particle beam on the object, a scan deflector for deflecting the particle beam such that an incidence location of the particle beam on the object can be displaced and a detector for detecting particles created at the object by the particle beam. The particle beam can be an electron beam or an ion beam.

According to embodiments, the method comprises successively directing the particle beam in a multiplicity of directions using the scan deflector such that the particle beam is successively incident on a multiplicity of incidence locations within a region of the object, detecting particles using the detector and creating a data record representing detected particles assigned to the respective directions. Different data records are obtained for different excitation settings of elements in the particle beam microscope, are analysed and possibly compared with one another in order to obtain values that form a basis for decisions relating to the change in the excitations of the particle-optical elements in the particle beam microscope.

In this case, the region of the object in which the multiplicity of incidence locations are located is a region that is elongate in a determined direction. For instance, the region has an extent in the determined direction that is more than ten times greater or more than fifty times greater than the extent in the direction orthogonal thereto.

In a conventional method for setting the particle beam microscope, test images respectively obtained by scanning a rectangular region with an aspect ratio of for example 1 to 2 are obtained, analysed and compared with one another.

The inventor has recognized that the recorded images which represent data suitable for finding suitable settings of the excitations of the elements in the particle beam microscope can be unnecessarily large with regard to finding settings of excitations of specific elements in the particle beam microscope. With regard to finding suitable settings of specific elements in the particle beam microscope, the inventor has also recognized that sufficient data to achieve this end can be obtained by scanning elongate regions on the object provided the elongate regions have a suitable orientation, i.e. the respective directions of extent of the elongate regions have been chosen in suitable fashion.

According to exemplary embodiments, the incidence locations of the particle beam on the object within the elongate region are located on one or more straight lines which extend on the object in a determined direction. In this case, the data offering the basis for finding an optimized setting can be obtained particularly quickly by virtue of the particle beam being directed at for instance 100 or 1000 incidence locations which are located on a straight line. Given a suitable choice for the orientation of the line, the obtained data can be used to improve a setting of the particle microscope, while images containing 100×100 or 1000×1000 pixels would be obtained to the same end within the scope of the conventional method. As a result of the reduction in the incidence locations used to obtain a data record, it is possible to obtain this data record comparatively more quickly and perform the method for setting the particle microscope accordingly more quickly.

According to exemplary embodiments, the particle beam microscope comprises a stigmator configured to astigmatically influence the particle beam and the method, for a given object direction, comprises the following measures: successively directing the particle beam in a multiplicity of directions with the scan deflector such that the particle beam is successively incident on the object at a multiplicity of incidence locations within an elongate region of the object oriented in the given object direction, detecting particles using the detector and creating a data record representing detected particles assigned to the respective deflections, evaluating the data record and ascertaining at least one value representing a measure for an image sharpness, and changing an excitation of the stigmator on the basis of the at least one value, with the object of improving the image sharpness. In this case, the method also comprises performing the measures for a first given object direction and performing the measures for a second given object direction which is oriented across the first given object direction. In the present disclosure, two directions are considered oriented across one another if they are not oriented parallel to one another and an angle between the directions differs from 0° and 180°. For instance, an angle between these two directions is greater than 10° and less than 170°.

According to exemplary embodiments herein, the smaller angle formed between the two directions lies between 10° and 80°, such as between 20° and 70°, for example between 30° and 60°.

The stigmator may be configured to collimate the particle beam in two mutually orthogonal collimation directions in a manner independently of one another, wherein the orientation of these two collimation directions is freely settable. For instance, the stigmator comprises eight coils which are arranged in the circumferential direction so as to be distributed around the particle beam that passes through the stigmator and which serve to create a quadrupole field, the strength and orientation of which around the particle beam needs to be set.

According to exemplary embodiments, the method further comprises multiple repetitions of performing the measures for the first given object direction and the measures for the second given object direction.

According to exemplary embodiments herein, the method further comprises changing an excitation of the objective lens on the basis of the at least one value ascertained when performing the measures for the first given object direction and/or when performing the measures for the second given object direction, with the object of improving the at least one measure for the image sharpness.

According to exemplary embodiments, a particle beam microscope comprises an adjustment deflector which is arranged in the beam path of the particle beam between the particle beam source and the objective lens and which is configured to deflect the particle beam and change the position thereof relative to the objective lens. Within the method for setting the particle beam microscope, excitations of the adjustment deflector are set such that the particle beam passes through the focusing fields of the objective lens as centrally as possible, with the result that errors when focusing the beam, which increasingly arise when the particle beam passes through the objective lens at an increased distance from the main axis of the latter, are avoided.

According to exemplary embodiments, the method for operating the particle beam microscope comprises directing the particle beam in a multiplicity of directions using the scan deflector such that the particle beam is successively incident on the object at a multiplicity of incidence locations within an elongate region of the object oriented in a given object direction, detecting particles, which were created at the object by the particle beam in the process, and creating a first data record representing detected particles assigned to the respective directions, subsequently changing a focusing of the particle beam on the object, and then renewed directing of the particle beam in a multiplicity of directions such that the particle beam is successively incident on the object at a multiplicity of incidence locations within a region oriented in the given direction, detecting particles and creating a second data record representing detected particles assigned to the respective directions. The method then also comprises evaluating the first and the second data record and ascertaining at least one value representing a measure for a displacement, and changing an excitation of the adjustment deflector on the basis of the value representing the displacement, with the object of reducing the displacement.

For instance, the particle beam focusing can be changed by changing the excitation of the objective lens, with an increase in the excitation of the objective lens leading to stronger focusing of the particle beam such that the distance between the focus of the particle beam and the objective lens is reduced. Focusing of the particle beam can also be achieved by changing the kinetic energy of the particles passing through the objective lens, with a reduction in the kinetic energy leading to stronger focusing of the particle beam and hence likewise leading to a reduction in the distance between focus and objective lens. For instance, the kinetic energy of the particles in the particle beam passing through the objective lens can be attained by changing acceleration voltages during the creation of the particle beam with the particle beam source.

Thus, the first and the second data record are obtained with different settings of the focusing. If the particle beam passes through the objective lens centrally along the main axis of the latter, then the focus of the particle beam is also located on the main axis and the same elongate regions of the object are scanned when the first and the second data record are obtained, and so a displacement of zero is determined during the evaluation of the data records.

If the particle beam passes through the objective lens at a distance from the main axis of the latter, then the focus likewise arises at a location arranged at a distance from the main axis, with this distance changing with the focusing. Accordingly, the elongate regions of the object scanned when obtaining the first and the second data record are different by virtue of being offset from one another. A value representing this displacement then serves as the basis for changing the excitation of the adjustment deflector, with the object of reducing the displacement. This method can be performed repeatedly until the displacement is sufficiently small and the particle beam thus passes substantially centrally through the objective lens.

According to exemplary embodiments, the adjustment deflector can deflect the particle beam in two mutually independent directions, for instance an x-direction and a y-direction when the main axis of the objective lens extends in a z-direction. The change in the deflection of the adjustment deflector in the two independent directions leads to displacements, in corresponding different directions, of the regions of the object scanned when the data records are obtained. It is for this reason that the method is performed for two different elongate regions of the object which differ in terms of their orientation on the object, so that the excitation of the adjustment deflector can be changed for the two different directions.

According to exemplary embodiments, the first and the second object direction are oriented orthogonally to one another.

According to exemplary embodiments, the particle beam microscope also comprises a condenser arranged in the beam path of the particle beam between the particle beam source and the objective lens and configured to collimate the particle beam. Like the objective lens, the condenser also provides magnetic and/or electric fields which have a focusing effect on the particle beam, with the result that the condenser and the objective lens together focus the particle beam on the object. For example, the condenser and the objective lens are able to image an emitter of the particle beam source in particle-optical fashion on the surface of the object.

In embodiments, the condenser is further away from the object than the objective lens, with the result that when it is only the condenser that produces the focusing effect on the particle beam, the latter is incident on the object with a convergence angle that is as small as possible or with a numerical aperture that is as small as possible. If, conversely, the focusing effect is produced by the objective lens alone, then the beam is incident on the object with a numerical aperture that is as large as possible. By changing the ratio between the excitations of the condenser and the objective lens, it is thus possible to set the convergence or the numerical aperture of the particle beam on the object.

In embodiments, the numerical aperture of the particle beam upon incidence on the object influences both the maximally attainable resolution of an image obtained by the particle beam and the depth of field thereof. A higher numerical aperture of the beam leads to a higher attainable resolution but a lower depth of field, and vice versa. For structured objects with an extent in the direction of the particle beam, it is desirable to set the depth of field such that all regions of the extended object are imaged with an acceptable sharpness. This can be achieved by targeted setting of the excitation of the condenser and, accordingly, of the objective lens.

In some cases, the object consists in creating an image of a substantially planar object arranged at a tilt in front of the objective lens, with the result that a surface normal of a main surface of the object makes an angle of, for instance, greater than 10° and less than 80° with the direction of the particle beam incident on the surface.

According to exemplary embodiments, a method for operating a particle beam microscope in such a situation comprises determining an object direction on the main surface of the object such that it is oriented across a direction on the main surface of the object which is oriented orthogonally to the beam direction. The method then a further comprises determining an elongate region of the object such that it is oriented in the determined object direction, directing the particle beam at a multiplicity of incidence locations within the determined region of the object, detecting particles and creating a data record representing detected particles assigned to the respective incidence locations, evaluating the data record and ascertaining at least one value representing a measure for an image sharpness, and changing an excitation of the condenser and the objective lens on the basis of the at least one value, with the object of improving the image sharpness.

In embodiments, this method can be repeated multiple times until a desired image sharpness is attained for the entire elongate region. For example, multiple values representing the measure for the image sharpness can be ascertained from the data record. For instance, values representing a respective measure for the image sharpness in a portion can be determined for a plurality of portions of the elongate region. The excitation of the condenser can then be changed on the basis of the plurality of values such that a value derived from the plurality of values, for instance equaling the mean value of the values, becomes maximal.

In embodiments, once the above-described settings have been made, i.e. the excitations of the elements influencing the particle beam, for instance the excitations of the stigmator, adjustment deflector or condenser, have been set, it is possible to record a particle-microscopic image with the largely optimally set particle beam microscope. According to exemplary embodiments, this comprises directing the particle beam at a multiplicity of incidence locations within an image region of the object, detecting particles and creating a data record representing detected particles assigned to the respective incidence locations, wherein the image region on the object has a first extent in a first direction and a second extent in a second direction orthogonal to the first direction and wherein a ratio between the first extent and the second extent is greater than 0.5 and less than 2.0. The data record represents the particle beam-microscopic image of the image region which is not elongate but instead has a significant extent in both directions.

In embodiments, the disclosure also provides a computer program product which represents instructions that, when loaded onto a control computer of a particle beam microscope, cause the control computer to operate the particle beam microscope in accordance with one of the methods described in the aforementioned embodiments. The computer program product may comprise a data carrier, for instance a compact disc or a solid-state memory, in which the instructions are represented by magnetic, optical or electrical states. The computer program product may also comprise a signal sequence which is transferable for instance via a network, a data line, a wireless communications path or the like, wherein the signal sequence encodes information representing the instructions.

### BRIEF DESCRIPTION OF THE DRAWINGS

Embodiments of the disclosure are explained in detail below with reference to figures. In detail:

FIG. 1 shows a schematic cross-sectional illustration of a particle beam microscope;

FIG. 2 shows a flowchart of a method for operating the particle beam microscope from FIG. 1 in accordance with a first embodiment;

FIG. 3 shows a schematic illustration of object regions used in the method from FIG. 2;

FIG. 4 shows a graphical representation of data obtained in the method from FIG. 2;

FIG. 5 shows a flowchart of a method for operating the particle beam microscope from FIG. 1 in accordance with a second embodiment;

FIG. 6 shows a graphical representation of data obtained in the method from FIG. 5;

FIG. 7 shows a flowchart of a method for operating the particle beam microscope from FIG. 1 in accordance with a third embodiment; and

FIG. 8 shows a graphical representation of data obtained in the method from FIG. 7.

### DETAILED DESCRIPTION

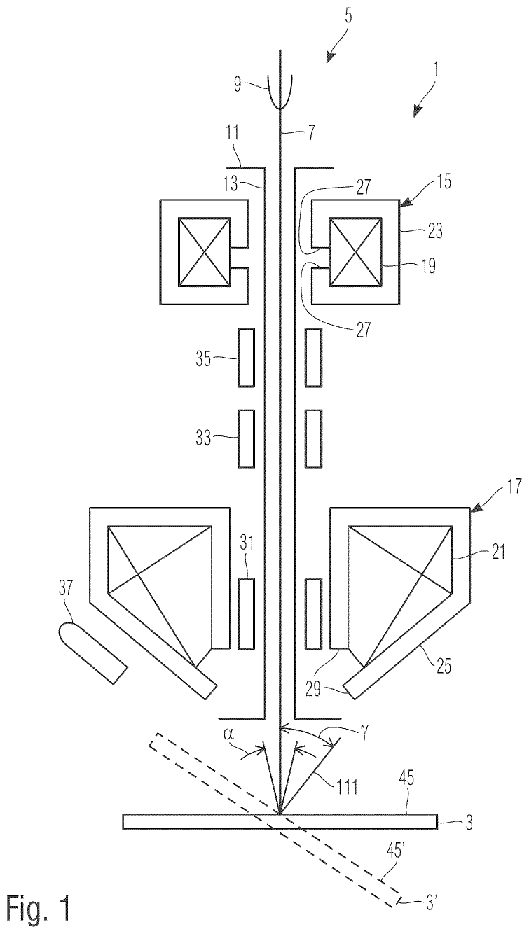

FIG. 1 is a schematic cross-sectional view of a particle beam microscope 1 for obtaining particle beam-microscopic images of an object 3. The particle beam microscope 1 comprises a particle beam source 5, which is configured to create a particle beam 7. The particle beam 7 can be an ion beam, with the result that the particle beam microscope 1 is an ion microscope. In the example described here, the particle beam 7 is an electron beam, and the particle beam microscope 1 is an electron microscope. The particle beam source 5 comprises an electron emitter 9 and an anode 11, between which a voltage is applied such that the electrons emerging from the electron emitter 9 are accelerated towards the anode 11 and enter into a beam tube 13 through the anode. The particle beam 7 passes through the beam tube 13 and emerges from its lower end in FIG. 1, prior to being incident on the surface of the object 3. Electric fields between the lower end of the beam tube 13 and the object 3 or between possible further electrodes provided between the lower end of the beam tube 13 and the object 3 can be used to decelerate the particles in the particle beam prior to the incidence thereof on the surface of the object 3 and set the kinetic energy of the particles upon incidence on the object 3.

The particle beam 7 emerging divergently from the electron emitter 9 is collimated by a collimator 15 and focused on the surface of the object 3 by an objective lens 17, wherein electrostatic fields between the lower end of the beam tube 13 and the surface of the object 3 and possibly further electrodes present may likewise have a focusing effect on the particle beam 7. The particles in the particle beam 7 focused on the surface of the object 3 are incident convergently on the surface of the object 3. In FIG. 1, a convergence angle of the focused particle beam 7 is represented schematically as angle α.

In the example described here, the collimator 15 and the objective lens 17 are magnetic lenses which provide magnetic fields that focus the particle beam 7 and which to this end each comprise an energized coil 19 or 21 and a yoke 23 or 25 with pole ends 27 or 29. The excitation of the condenser 15 is settable by virtue of setting the current flowing through the coil 19. Accordingly, the excitation of the objective lens 17 is settable by virtue of setting the current flowing through the coil 21. It is possible here, while maintaining the focusing of the particle beam 7 on the surface of the object 3, to change the ratio with which the collimator 15 and the objective lens 17 contribute to the focusing of the particle beam 7. If the collimator 15 is excited to a lesser extent and the objective lens 17 is excited to a greater extent, then the convergence angle α is greater than in a situation where the collimator is excited to a greater extent and the objective lens 17 is accordingly excited to a lesser extent. This means that changing the excitation of the collimator 15 and accordingly adapting the excitation of the objective lens 17 such that the particle beam 7 remains focused on the surface of the object 3 allows the convergence angle α to be set within a certain range.

The particle beam microscope 1 also comprises a scan deflector 31 which is configured to deflect the particle beam for the purpose of displacing an incidence location of the particle beam 7 on the surface of the object 3. Excitations of the scan deflector 31 are settable for the purpose of setting, in two mutually independent directions, deflection angles through which the particle beam 7 is deflected when passing through the scan deflector 31. A change in the deflection angle by the scan deflector 31 leads to a corresponding change in the incidence location of the particle beam 7 on the surface of the object 3.

The particle beam microscope 1 also comprises a stigmator 33 which is configured to create a quadrupole field which has an astigmatic influence on the particle beam 7. For instance, the stigmator 33 comprises eight coils or electrodes which are arranged in the circumferential direction in a manner distributed around the particle beam, in order to create an electric or magnetic quadrupole field. Excitations of the elements of the stigmator 33 are settable for the purpose of setting a strength and an orientation of the quadrupole field. The stigmator 33 is used to compensate unwanted astigmatic effects of other particle-optical components, for instance of the condenser 15 or of the objective lens 17, with the result that the particle beam 7 focused on the surface of the object 3 can illuminate a small substantially circular spot there.

The particle beam microscope 1 also comprises an adjustment deflector 35, which is arranged in the beam path of the particle beam 7 between the particle source 5 and the objective lens 17. Excitations of the adjustment deflector 35 are settable for the purpose of deflecting the particle beam 7 such that the position of the latter is changed relative to the objective lens 17. The excitations of the adjustment deflector 35 are set such that the particle beam 7 passes through the objective lens 17 as centrally as possible, i.e. along a main axis of the objective lens 17. In this case, a smaller and better focus of the particle beam 7 on the surface of the object 3 can be obtained in comparison with the situation in which the particle beam 7 passes through the objective lens at a distance from the main axis thereof.

The particle beam microscope 1 also comprises a detector 37 for detecting particles which are created on the object 3 by the incidence of the particles in the particle beam 7. For instance, these particles are electrons, such as so-called backscattered electrons, which emanate from the object 3 with a kinetic energy that is equal to or slightly less than the kinetic energy with which the electrons in the particle beam 7 are incident on the object, or so-called secondary electrons, which emerge from the object 3 with kinetic energies of approximately 50 eV or less.

To obtain a particle-microscopic image of the object 3, the particle beam 7 is successively directed to a multiplicity of incidence locations within an image region of the object 3 by actuating the scan deflector 31, the detector 37 is used to detect particles created in the process, and a data record representing detected electrons assigned to the excitations of the scan deflector 31, and hence accordingly assigned to the incidence locations, is created. This data record represents a particle-microscopic image of the object and, for instance, can be displayed on a display by virtue of the number of particles assigned to the incidence locations being represented by a brightness and the incidence location being represented by a position in the image.

The image region scanned during the recording of the particle-microscopic image has a significant extent in two mutually independent directions on the surface of the object, for instance in an x-direction and in a y-direction. For instance, an aspect ratio of the image region, i.e. a ratio between the extent of the image region in the x-direction and the extent of the image region in the y-direction, is 1:1 or 2:1 or the like.

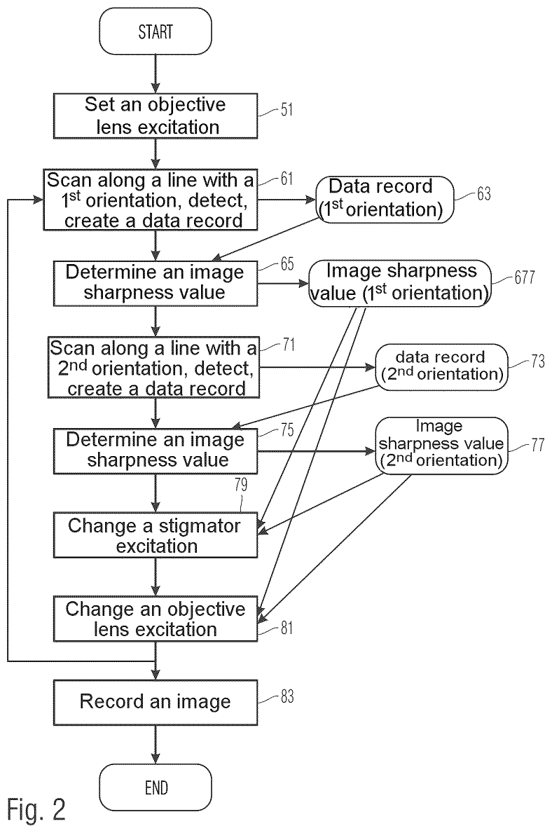

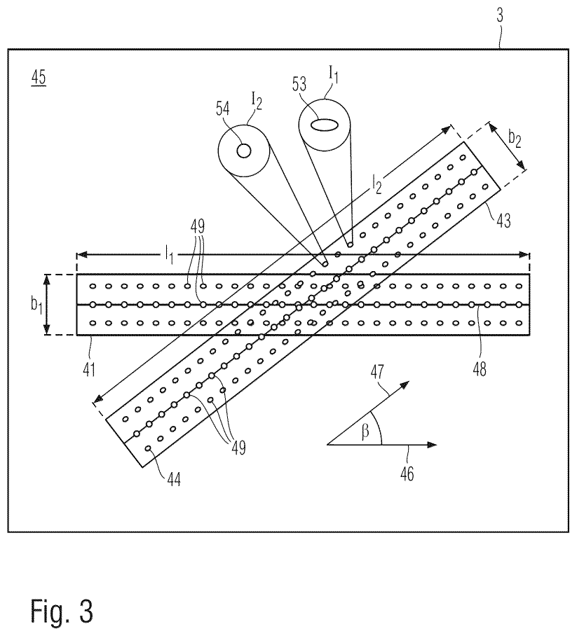

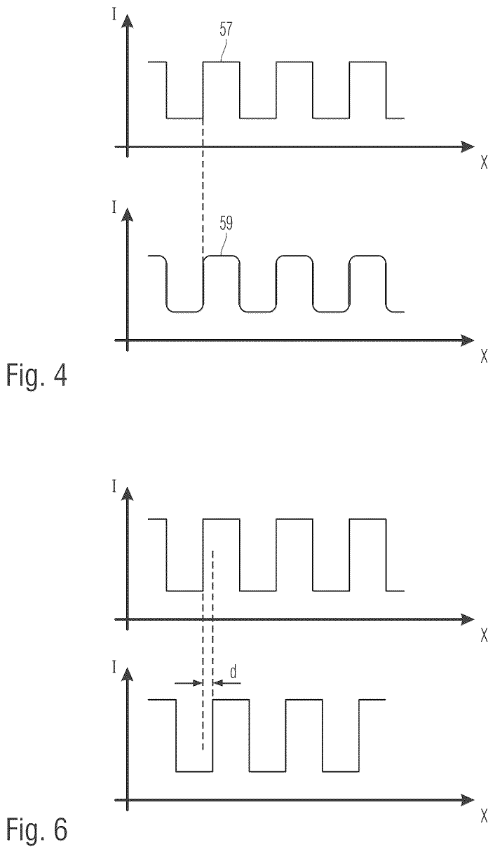

A method for setting the excitations of the stigmator 33 is explained below on the basis of FIGS. 2 to 4. In this case, FIG. 2 shows a flowchart of the method, FIG. 3 shows a schematic illustration of object regions used during this method and FIG. 4 shows a graphical representation of data obtained with this method.

In the embodiment of the method from FIG. 2, elongate object regions 41 and 43 on the surface 45 of the object 3 are scanned. In this case, the object region 41 has an elongate extent in an object direction, for instance the x-direction, specified by an arrow 46, while the object region 43 has an elongate extent in an object direction depicted by an arrow 47. The two object directions are not parallel to one another. For example, the smaller angle between the two object directions is greater than 10° and less than 80°, such as greater than 20° and less than 70°, for example greater than 30° and less than 60°. The two object directions 46 and 47 can be oriented at an angle β of 45° with respect to one another, with other orientations being possible. In the object direction 46, the elongate object region 41 has a length 11 which is more than 10 times or more than 100 times greater than a width b1 of the surface region 41 as measured orthogonally to the object direction 46. The elongate surface region 41 contains incidence locations 49, at which the particle beam is successively directed during the scanning of the elongate surface region 41. In FIG. 3, the incidence locations 49 are arranged next to one another in three rows, in each case with approximately the same spacings, in the direction 46 and the direction orthogonal thereto. The incidence locations 49 in the elongate surface region 41 can be scanned row by row, column by column, in zigzag fashion or with a random sequence in any desired sequence.

In some embodiments, the region 41 contains only incidence locations located on a single straight line 48 that extends in the object direction 46, with the result that the elongate region 41 likewise has the extent 11 in the object direction 46, while its width b1 in the direction orthogonal to the object direction 47 is infinitesimally small or reduced to the diameter of the beam foci at the incidence locations 49.

In a corresponding manner, the surface region 43 is elongate in the object direction 47 by virtue of having a length 12 in the object direction 47 which is multiple times greater, for instance 10 times greater or 100 times greater, than a width b2 in the direction orthogonal to the direction 47. Three rows of incidence locations 49 oriented in the object direction 47 are also depicted in the elongate surface region 43. In some embodiments there is only one row of incidence locations 49, which are located on a straight line 44 extending in the object direction 47.

The method shown in FIG. 2 serves to optimize the setting of the stigmator 33. Once the method has been started, the excitation of the objective lens 17 is set with a conventional method in step 51 such that the particle beam microscope 1 could already be used to record images, albeit still with an unsatisfactory quality since the optimal setting of the stigmator 35 has not yet been found. An enlarged image part I1 in FIG. 3 shows a beam spot 35, illuminated at an incidence location 49, on the surface 45 of the object 3 if the focusing of the particle beam 7 has an astigmatic disturbance. It is evident that the beam spot 53 has an oval form that is stretched in the object direction 46. The enlarged part 12 in FIG. 3 shows a beam spot 54 without astigmatic distortion; it has the form of a small circle.

In an upper part, FIG. 4 shows a graph specifying, by way of a line 57, the intensity I detected by the detector 37 as a function of location when scanning the line 48 in the object direction 46 if the assumption is made that a chequerboard-like pattern has been applied to the object 3 and the beam spot 54 has the optimized form shown in the enlarged part 12 in FIG. 3. Scanning this structure in the object direction 46 leads to the alternating detection of elevated and reduced intensities, with the transition between these having a sharp edge and being steep. The lower graph in FIG. 4 is a representation corresponding to the upper graph and shows, by way of a line 59, the detected intensity I when scanning in the object direction 46, wherein the beam spot has the astigmatically ovally distorted form shown in the image part I1 in FIG. 3. On account of the greater extent of the beam spot 53 in the object direction 46, the intensity changes when scanning the chequerboard-like structure do not have such sharp edges and are not as steep as in the case of the upper graph in FIG. 4. If the particle beam 7 creating the beam spot 53 shown in the image part I1 is scanned in the object direction 47, a curve representing the detected intensities would tend to have the shape with the sharp and steep edges of the curve 57 rather than the shape of the curve 59 since the beam spot 53 has a substantially smaller extent in the object direction 47 than in the object direction 46.

It is thus evident that the shape of the curves 57, 59 when scanning the structure in the object directions 46 and 47 allows conclusions to be drawn as to whether the focus of the particle beam has an astigmatic distortion and as to the direction of the distortion. From this, it is possible to determine excitations or changes in the excitations of the elements in the stigmator 33 which reduce the astigmatic distortion of the particle beam at the surface 45 of the object 3.

The smaller the extent of the beam spot 53, 54 in the object direction 46, 47 in which the scanned region 41, 43 extends, the more sharply the structures of the object are identifiable in the detected intensities. Conversely, the structures in the detected intensities are less sharp, more rounded or more washed out as the extent of the beam spot 53, 54 increases in the scanned object direction 46, 47. There are conventional methods in the field of image processing that allow the derivation of values from curves, for instance the curves 57 and 59, the values representing a measure of image sharpness and being suitable with regards to forming the basis for an optimization method for setting the stigmator 33. For example, the curve 57, 59 can be subject to a Fourier transform in order to obtain a frequency spectrum, and the value of the highest frequency present in the frequency spectrum can be used as a value representing the image sharpness. It is evident that this value would be higher for the curve 57 than for the curve 59.

In the method of FIG. 2, the first setting in step 51 is followed in a step 61 by the particle beam 7 being scanned along the line 48 oriented in the object direction 46 by actuating the scan deflector 31; the detector 37 is used to detect the corresponding particles created during the scanning, and a first data record 63 representing the detected particles assigned to the respective incidence locations is created. This data record can be depicted graphically, for example like in curves 57 and 59 in FIG. 4. The data record 63 is evaluated in a step 65 in order to determine an image sharpness value 67. For instance, the image sharpness value 67 can be the above-described highest frequency in the frequency spectrum of the depicted line. Subsequently, steps 61, 65 and 69 are performed for the second orientation by virtue of, in a step 71, the particle beam 7 being scanned along the straight line 44 in the object direction 47, the intensities being detected and a data record 73 being created, the latter being evaluated in a step 75 in order to determine a corresponding image sharpness 77 in turn. Then, the excitations of the elements in the stigmator 31 are changed in a step 79 on the basis of the determined image sharpness value 67 for the first orientation and the image sharpness value 77 for the second orientation, to be precise with the object of improving the image sharpness. Thereupon, the excitation of the objective lens 17 can also be slightly modified on the basis of the image sharpness values 67 and 77 in a step 81 if both image sharpness values 66 and 67 are the same but can still be improved by changing the focusing of the objective lens 17.

Once a satisfactory setting has been found, i.e. the image sharpness values 67 and 77 have attained a desired magnitude, the stigmator 33 of the particle beam microscope 1 is set to a sufficient degree, and a desired particle-microscopic image can be recorded in a step 83. If the satisfactory setting has not yet been found, the method can continue with step 61 after step 81, in order to repeat steps 61 to 81.

The changes in the excitation of the stigmator 33 in steps 69 and 79 and the changes in the excitation of the objective lens in step 81 are each implemented with the object of improving the image sharpness. As is conventional for optimization methods, the result in this context may deteriorate temporarily while the parameter space is scanned and for instance the method is guided out of a local minimum.

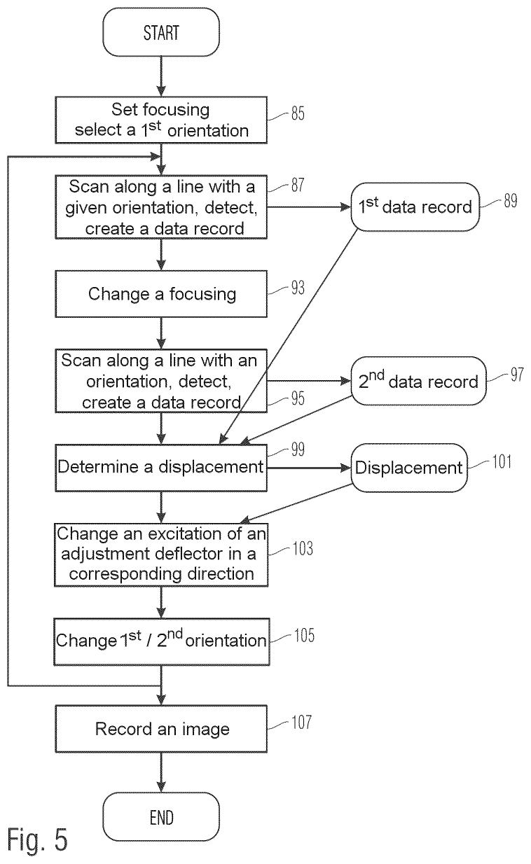

A method for setting the adjustment deflector 35 is explained below on the basis of FIGS. 5 and 6. In this case, FIG. 5 shows a flowchart of the method, and FIG. 6 shows a graphical representation of the data obtained during this method.

The method shown in FIG. 5 serves to set the adjustment deflector 35 such that the particle beam 7 passes through the objective lens 17 substantially centrally. To this end, the focusing is initially set to such an extent in a step 85 that, for instance, a particle-microscopic image could be recorded, albeit still with suboptimal quality. Further, the object direction 46, for instance, is initially selected as the first orientation. Then, the line 48 is scanned in a step 87 in a manner similar to step 61 in FIG. 2; the particles are detected and a first data record 89 representing the detected particles assigned to the respective incidence locations is created. This data record 89 can be represented graphically, for example in accordance with FIG. 4. The upper part of FIG. 6 shows an exemplary representation of the data record 89 by way of a line 91.

Subsequently, the focusing is changed slightly in a step 93. For instance, this can be achieved by changing the excitation of the objective lens 17 by changing the current flow through the coil 21 or by changing the kinetic energy of the particles in the particle beam 7 passing through the objective lens 17 by changing the voltage between the electron emitter 9 and the anode 11.

Following the change in the focusing in step 93, the particle beam 7 is re-scanned along the line 48 in a step 95 by virtue of using the same excitations of the scan deflector as in step 87 for the purpose of directing the particle beam 7 at the individual incidence locations. Hence, the particle beam 7 is also deflected through the same angles and in the same directions in steps 87 and 95. Further, particles created for the various deflection directions or incidence locations are detected in step 95, and a second data record 97 is created therefrom. An example of the data record 97 is depicted by way of the line 99 in the lower part of FIG. 6. It is evident from the comparison between lines 91 and 99 that the lines 91 and 99 have an offset d relative to one another. This offset d can be traced back to the fact that the particle beam 7 does not pass centrally through the objective lens 17 and hence is not only focused but also slightly deflected by the objective lens 17. By changing the focusing in step 93, the magnitude of this deflection is modified, leading to the offset d between the two curves 91 and 99. Conversely, the offset d determined from the comparison of the two data records 89 and 97 can be used to modify the excitation of the adjustment deflector 35, with the object of reducing this offset d.

Hence, the data record 89 and the data record 97 are compared with one another in a step 99 for the purpose of determining a displacement 101 that corresponds to the offset d.

The excitation of the adjustment deflector 35 is changed in a step 103 on the basis of the displacement 101, to be precise for a deflection direction of the adjustment deflector 35 which corresponds to the object direction in which the line scanned in steps 87 and 95 is oriented. The object of this change in the excitation of the adjustment deflector 35 is that of reducing the displacement 101.

Then, the orientation used in steps 87 to 103 is changed in a step 105, i.e. if the orientation used in steps 87 to 103 is the first orientation in the object direction 46, then the orientation is changed to the 2nd orientation which is oriented in an object direction that can be orthogonal to the object direction 46, with other object directions being possible. Conversely, if the orientation used in the steps is the second orientation, then the orientation is changed to the first orientation. In the method explained here on the basis of FIG. 6, use is made of two non-parallel object directions. For example, the smaller angle between the two object directions can be greater than 60°, such as greater than 70°, for example greater than 80°. The two object directions 46 and 47 depicted in FIG. 3 can be oriented orthogonally to one another here.

Then, the method is continued with step 87, and steps 87 to 103 are performed with the corresponding other orientation in order to improve the excitation of the adjustment deflector 35 for the corresponding other direction as well. Should it emerge after step 105 that the displacements 101 determined for two different orientations are sufficiently small, then the optimization of the adjustment deflector 35 is complete, and a desired particle-microscopic image can be recorded with a high quality in a step 107. Otherwise, the method is continued at step 87 again.

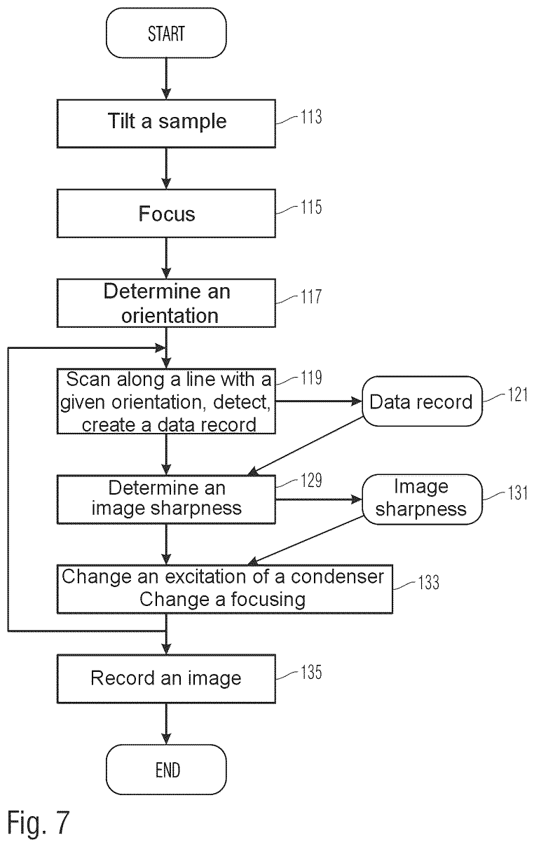

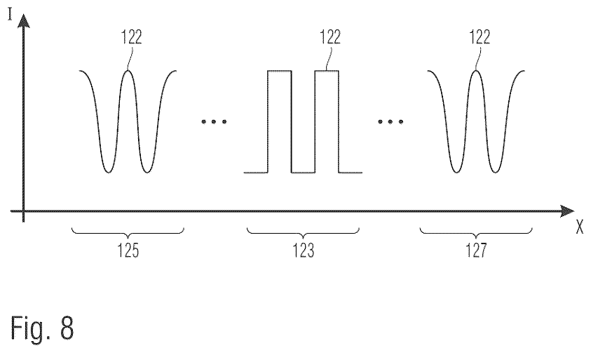

A method for setting the convergence angle α is explained below on the basis of FIGS. 7 and 8. In this case, FIG. 7 shows a flowchart of the method, and FIG. 8 shows a graphical representation of the data obtained during this method.

Such a method can advantageously be used if the object to be imaged in particle-microscopic fashion comprises a structure which has a significant extent in the direction of the particle beam. An example of such an object is the object 3′, which is depicted using a dashed line in FIG. 1 and which comprises a planar main surface 45′ that is tilted relative to the main surface 45 of the object 3 depicted using the solid line. For example, the main surface 45′ has a surface normal 111 which makes an angle α of for instance 20° with the direction of the particle beam 7. It is evident that incidence locations on the surface 45′ of the object 3′ located in an image field to the left in the illustration of FIG. 1 are arranged substantially closer to the objective lens 17 than incidence locations located in the image field to the right. It is therefore desirable for the created particle-microscopic images to have a sufficient depth of field such that the entire imaged region of an image field appears with a sufficient image sharpness in the created image.

In the method of FIG. 7, the object is accordingly tilted in an initial step 113 in accordance with the desired properties such that the angle γ between the surface normal 111 of the main surface 45′ and the direction of the particle beam 7 upon incidence on the object 3′ is greater than for instance 10°. In a step 115, the focusing of the particle beam microscope 1 is set such that an image of the object 3′ could be created, although the setting of the particle beam microscope 1 is still suboptimal in relation to image sharpness and depth of field.

Subsequently, an orientation for a subsequent line scan is determined as follows in a step 117: There is a straight line located on the main surface 45′ which runs through the incidence location of the particle beam 7 on the main surface 45′ and which is oriented orthogonally to the direction of the particle beam 7. In the illustration of FIG. 1, this straight line runs orthogonally to the plane of the drawing. The direction determined in step 117 is oriented across the direction of this straight line. For example, this direction can be oriented orthogonally to this straight line.

In a step 119, a line 48 oriented in the determined direction is scanned; the particles arising when this line 48 is scanned are detected, and a data record 121 representing the detected particles assigned to the respective incidence locations is created.

An exemplary graphical representation of the data record 121 is shown by way of curves 122 in FIG. 8. Here, the assumption is made that a chequerboard pattern is once again scanned, the latter leading to a dependence of the detected particle intensity I on the location×that is similar to that in the representations in FIGS. 3 and 6. The image sharpness is not the same along the entire length of the line 48 on account of the significant extent of the object 3′ in the direction of the particle beam 7 and a limited depth of field. Rather, the example illustrated in FIG. 8 has a central region 123 with a high image sharpness, which is evident from the comparatively sharp edges of the curve 122 in this region, and a left region 125 and a right region 127, in which the image sharpness is lower in each case, as identified by the rounded-off curves 122.

Values of the image sharpness are determined in a step 129 for a plurality of regions along the line. For instance, a respective image sharpness value is determined for three different regions along the line 48, with the result that for instance three values 131 representing the image sharpness are determined. The excitation of the condenser and of the objective lens is changed in a step 133, to be precise with the object of improving the values of the image sharpness 131. For instance, this can be implemented by virtue of optimizing the sum of the values representing the image sharpness of the individual regions.

Subsequently, steps 119, 129 and 133 can be carried out repeatedly until a sufficient image sharpness is obtained for all regions along the line 48, whereupon a desired particle-microscopic image can be recorded with a high quality in a step 135.

What is claimed is:

1. A method of operating a particle beam microscope, the particle beam microscope comprising: a particle beam source configured to create a particle beam; an objective lens configured to focus the particle beam on an object; a stigmator configured to astigmatically influence the particle beam; a scan deflector configured to deflect the particle beam in order to displace an incidence location of the particle beam on the object; and a detector configured to detect particles created at the object by the particle beam, the method comprising:
successively directing the particle beam in a multiplicity of directions by actuating the scan deflector so that the particle beam is successively incident on the object at a multiplicity of incidence locations within a region of the object oriented in an object direction, the region of the object in the object direction having an extent that is at least 10 times greater than an extent of the region of the object in a direction orthogonal to the object direction;
detecting particles using the detector and creating a data record representing detected particles assigned to the respective directions;
evaluating the data record and ascertaining at least one value representing a measure of an image sharpness; and
changing an excitation of the stigmator based on the at least one value to improve the measure of the image sharpness,
wherein the method further comprises:
performing the measures for a first object direction; and
performing the measures for a second object direction oriented across the first object direction.

2. The method of claim 1, wherein:
the stigmator is configured so that, when the stigmator is excited, the stimgmator provides a quadrupole field with an adjustable strength and orientation; and
a smaller angle between the first object direction and the second object direction lies between 10° and 80°.

3. The method of claim 1, further comprising repeatedly performing: i) the measures for the first object direction; and ii) the measures for the second object direction.

4. The method of claim 1, further comprising changing an excitation of the objective lens based on at least one value ascertained when performing the measures for the first object direction and/or the measures for the second object direction, thereby improving the measure for the image sharpness.

5. The method of claim 1, wherein a smaller angle between the first object direction and the second object direction is greater than 60°.

6. The method of claim 1, wherein the multiplicity of incidence locations within the region of the object are on a straight line.

7. The method of claim 1, wherein:
after changing the excitation of the stigmator, the method comprises directing the particle beam at a multiplicity of incidence locations within an image region of the object by actuating the scan deflector, detecting particles using the detector and creating a first data record representing detected particles assigned to the respective incidence locations;
the image region has a first image region extent in a first image region direction;
the image region has a second image region extent in a second image region direction orthogonal to the first image region direction; and
a ratio of the first image region extent to the second image region extent is between 0.5 and 2.0.

8. One or more machine-readable hardware storage devices comprising instructions that are executable by one or more processing devices to perform operations comprising the method of claim 1.

9. A system comprising:
one or more processing devices; and
one or more machine-readable hardware storage devices comprising instructions that are executable by the one or more processing devices to perform operations comprising the method of claim 1.

10. A method of operating a particle beam microscope, the particle beam microscope comprising: a particle beam source configured to create a particle beam; an objective lens configured to focus the particle beam on an object; a scan deflector configured to deflect the particle beam in order to displace an incidence location of the particle beam on the object; an adjustment deflector configured to deflect the particle beam in order to change the position thereof relative to the objective lens; a detector configured to detect particles created at the object by the particle beam, the method comprising:
a) successively directing the particle beam in a multiplicity of directions by actuating the scan deflector so that the particle beam is successively incident on the object at a multiplicity of incidence locations within a region of the object oriented in an object direction, detecting particles using the detector and creating a first data record representing detected particles assigned to the respective directions, the region of the object in the object direction having an extent that is at least 10 times greater than an extent of the object in the region in a direction orthogonal to the object direction;
b) after a), changing a focusing of the particle beam on the object;
c) after b), successively directing the particle beam in a multiplicity of directions by actuating the scan deflector such that the particle beam is successively incident on the object at a multiplicity of incidence locations within a region of the object oriented in the first direction, detecting particles using the detector and creating a second data record representing detected particles assigned to the respective directions;
d) evaluating the first and the second data records and ascertaining at least one value representing a measure for a displacement; and
e) changing an excitation of the adjustment deflector based on the at least one value representing the measure for the displacement to reduce the displacement,
wherein the method further comprises:
performing the measures for a first object direction; and
performing the measures for a second object direction which is oriented across the first direction.

11. The method of claim 10, wherein b) comprises changing a kinetic energy of the particles of the particle beam passing through the objective lens and/or changing an excitation of the objective lens.

12. The method of claim 10, wherein a smaller angle between the first object direction and the second object direction is greater than 60°.

13. The method of claim 10, wherein the multiplicity of incidence locations within the region of the object are on a straight line.

14. The method of claim 10, further comprising changing an excitation of the objective lens based on the at least one value to improve the image sharpness.

15. The method of claim 10, wherein:
after changing the excitation of the stigmator, the method comprises directing the particle beam at a multiplicity of incidence locations within an image region of the object by actuating the scan deflector, detecting particles using the detector and creating a first data record representing detected particles assigned to the respective incidence locations;
the image region has a first image region extent in a first image region direction;
the image region has a second image region extent in a second image region direction orthogonal to the first image region direction; and
a ratio of the first image region extent to the second image region extent is between 0.5 and 2.0.

16. A method of operating a particle beam microscope, the particle beam microscope comprising: a particle beam source configured to create a particle beam; an objective lens configured to focus the particle beam on an object; a condenser arranged in the beam path of the particle beam between the particle beam source and the objective lens and configured to collimate the particle beam; a scan deflector configured to deflect the particle beam in order to displace an incidence location of the particle beam on the object; and a detector configured to detect particles created at the object by the particle beam, the method comprising:
arranging the object such that a surface normal of a main surface of the object makes an angle between 10° and 80° with a direction of the particle beam incident on the surface;
determining an object direction in the plane of the main surface of the object so that the objection direction is oriented across a direction in the plane of the main surface of the object which is oriented orthogonally to a direction of the particle beam incident on the object;
successively directing the particle beam in a multiplicity of directions by actuating the scan deflector such that the particle beam is successively incident on the object at a multiplicity of incidence locations within a region of the object oriented in the object direction, detecting particles using the detector and creating a data record representing detected particles assigned to the respective directions;
evaluating the data record and ascertaining at least one value representing a measure for an image sharpness; and
changing an excitation of the condenser based on the at least one value representing the measure for the image sharpness to improve the image sharpness,
wherein the region of the object in the first direction has an extent that is at least 10 times greater than an extent of the object in the region in a direction orthogonal to the first direction.

17. The method of claim 16, further comprising repeatedly directing the particle beam at the multiplicity of incidence locations, detecting particles, creating the data record, evaluating the data record and ascertaining the at least one value representing the measure of the image sharpness, and changing the excitation of the condenser based on the basis of the at least one value representing the measure for the image sharpness to improve the image sharpness.

18. The method of claim 16, further comprising changing an excitation of the objective lens based on the at least one value representing the measure for the image sharpness to improve the image sharpness.

19. The method of claim 16, wherein the multiplicity of incidence locations within the region of the object are on a straight line.

20. The method of claim 16, wherein:
after changing the excitation of the stigmator, the method comprises directing the particle beam at a multiplicity of incidence locations within an image region of the object by actuating the scan deflector, detecting particles using the detector and creating a first data record representing detected particles assigned to the respective incidence locations;
the image region has a first image region extent in a first image region direction;
the image region has a second image region extent in a second image region direction orthogonal to the first image region direction; and
a ratio of the first image region extent to the second image region extent is between 0.5 and 2.0.
